(19) United States
(12) Patent Application Publication
(10) Pub. No.: US 2026/0371989 A1
(43) Pub. Date: Nov. 19, 2026

(54) HEAT TREATMENT APPARATUS AND HEAT TREATMENT METHOD

(71) Applicant: Tokyo Electron Limited, Tokyo (JP)

(72) Inventors: Kousuke HISADA, Kumamoto (JP); Hiroaki KURISHIMA, Kumamoto (JP); Toshiki NAEKI, Tainan City (TW)

(21) Appl. No.: 19/470,471

(22) PCT Filed: Apr. 4, 2024
(86) PCT No.: PCT/JP2024/013902

§ 371 Date: Sep. 29, 2025

(30) Foreign Application Priority Data
Apr. 11, 2023 (JP) 2023-064296

(51) Int. Cl. H10P 72/00; H05B 1/02

(52) U.S. Cl. CPC H10P 72/0434; H05B 1/0233

(57) ABSTRACT

A heat treatment apparatus includes a heating unit that supports and heats a substrate to a high temperature of 500 °C or higher, a chamber including a lid part that covers the heating unit to define a treatment space above the heating unit and has a surface formed of a metal-containing material on a side of the treatment space, and an exhaust unit that exhausts the treatment space. The chamber includes a gas supply unit that supplies a low humidity gas having lower humidity than atmospheric air to the treatment space.

### TECHNICAL FIELD

The present disclosure relates to a heat treatment apparatus and a heat treatment method.

### BACKGROUND

The heat treatment unit disclosed in Japan Patent Laid-Open Publication No. 2022-007534 includes a heating unit that supports and heats a substrate with a film formed thereon, and a chamber that includes a peripheral wall part surrounding the heating unit and a lid part covering the heating unit with a gap from the peripheral wall part to form a treatment space above the heating unit. In addition, the heat treatment unit includes a housing that houses the heating unit and the chamber, a first gas supply unit that supplies a first gas having an oxygen concentration lower than that of atmospheric air to the treatment space, and an exhaust unit that exhausts the treatment space at an exhaust rate greater than the supply rate of the first gas. Further, the heat treatment unit includes a second gas supply unit that supplies a second gas having an oxygen concentration lower than that of atmospheric air to the gap between the peripheral wall part and the lid part, and a third gas supply unit that supplies a third gas having an oxygen concentration lower than that of atmospheric air to the outside of the chamber within the housing.

### PRIOR ART DOCUMENT

### Patent Document

Patent Document 1: Japanese Patent Laid-open Publication No. 2022-007534

### SUMMARY OF THE INVENTION

### Problem to be Solved

The technology according to the present disclosure prevents the generation of gas including a constituent metal of a component exposed to high temperature within a heat treatment apparatus from a surface of the component.

### Means to Solve the Problem

An aspect of the present disclosure relates to a heat treatment apparatus including a heating unit configured to support and heat a substrate to a high temperature of 500 °C or higher, a chamber including a lid part that covers the heating unit to form a treatment space above the heating unit and has a surface formed of a metal-containing material on a side of the treatment space, and an exhaust unit configured to exhaust the treatment space,
in which the chamber includes a gas supply unit configured to supply a low humidity gas having lower humidity than atmospheric air to the treatment space.

### Effect of the Invention

According to the present disclosure, it is possible to prevent the generation of gas including a constituent metal of a component exposed to high temperature within a heat treatment apparatus from a surface of the component.

### BRIEF DESCRIPTION OF THE DRAWINGS

FIG. 1 is an explanatory view illustrating an outline of an internal configuration of a coating and developing system as a substrate processing system, which includes a heat treatment apparatus, according to the present embodiment.

FIG. 2 is a view illustrating an outline of the internal configuration of the coating and developing system on the front side.

FIG. 3 is a view illustrating an outline of the internal configuration of the coating and developing system on the rear side.

FIG. 4 is a vertical sectional view schematically illustrating an outline of a configuration of a high-temperature heat treatment apparatus.

FIG. 5 is a vertical sectional view schematically illustrating an outline of a configuration inside a heating area.

FIG. 6 is a flowchart illustrating an example of processing by a coating and developing system.

FIGS. 7A and 7B are explanatory views illustrating an operation of a high-temperature heat treatment apparatus.

FIGS. 8A and 8B are explanatory views illustrating the operation of the high-temperature heat treatment apparatus.

FIGS. 9A and 9B are explanatory views illustrating the operation of the high-temperature heat treatment apparatus.

FIG. 10 is an explanatory view illustrating the operation of the high-temperature heat treatment apparatus.

FIG. 11 is a partially enlarged cross-sectional view of a heating plate.

### DETAILED DESCRIPTION TO EXECUTE THE INVENTION

In a manufacturing process for semiconductor devices and the like, a photolithography process is performed on a substrate such as a semiconductor wafer (hereinafter, referred to as a “wafer”), forming a resist pattern on the substrate. Then, using this resist pattern as a mask, etching a layer to be processed is performed, so that a desired pattern is formed in the layer to be processed.

Meanwhile, with the miniaturization of semiconductor devices, etching with a high aspect ratio is required when etching the layer to be processed. For this purpose, a technology is known, which forms a hard mask layer having higher etching resistance than a resist film as an underlayer of the resist film and uses the hard mask layer as a mask for etching. In addition, with the appearance of the 3D NAND devices, etc., a hard mask layer having higher etching resistance is required.

The hard mask layer may be formed by a CVD method, but may also be formed by coating a processing solution for forming a mask layer with a higher throughput and heating the same. Further, in the latter case, it may be required to heat the substrate to a high temperature of 500 °C or higher.

However, heating to the high temperature of 500 °C or higher may lead to the generation of gas including a constituent metal of a component exposed to the high temperature within the heat treatment apparatus used for heating from the surface of the component. Specifically, for example, gas including chromium in stainless steel, which is a material of the chamber, may be generated from the chamber supporting the substrate and forms a treatment space above a heating plate. Furthermore, there is a concern that gases including metals (specifically, chromium) may adversely affect the substrate and devices related to the substrate.

Accordingly, the technology according to the present disclosure prevents the generation of gas including a constituent metal of a component exposed to high temperature within a heat treatment apparatus from a surface of the component.

In this regard, the inventors of the present disclosure have conducted intensive studies on this issue and have found that, when heating to a high temperature of 500 °C or higher, the amount of chromium detected is significantly reduced by changing the gas supplied to the treatment space from temperature and humidity-adjusted gas including moisture to nitrogen gas or dry air having humidity lower than that of atmospheric air. Specifically, the amount of chromium detected on the surface (front surface) of a wafer W was approximately 8.5×10¹⁰ atoms/cm² in the case of the temperature and humidity-adjusted gas, but approximately 0.1×10¹⁰ atoms/cm² in the case of nitrogen gas or dry air. This phenomenon may be attributed to the following reasons. That is, for heating to a high temperature of 500 °C or higher, when gas including moisture is supplied to the treatment space, a chromium oxide (Cr₂O₃) film formed on the surface of the chamber due to natural oxidation of the stainless steel reacts with the moisture (water vapor), etc., to produce chromium-containing gas (specifically, CrO₂(OH)₂). Meanwhile, when the gas supplied to the treatment space does not include moisture, the reaction described above does not occur, thus preventing the generation of chromium-containing gas. This is considered a possible reason.

The following embodiments are based on the knowledge described above.

Hereinafter, a heat treatment apparatus and a heat treatment method according to an embodiment will be described with reference to the drawings. In addition, throughout the descriptions herein and the drawings, elements having substantially the same function or configuration are denoted by the same reference numerals, and duplicate description thereof will be omitted.

### <Coating and Developing System>

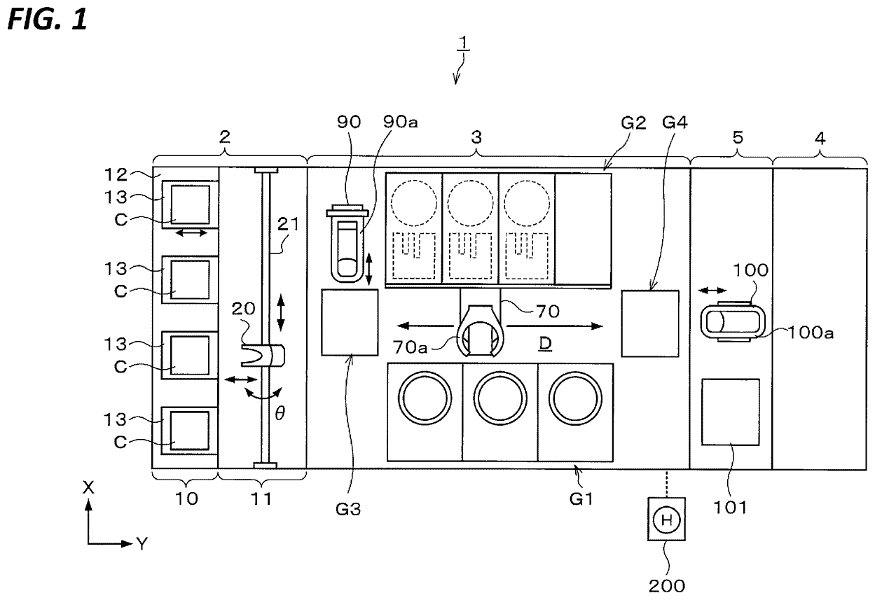

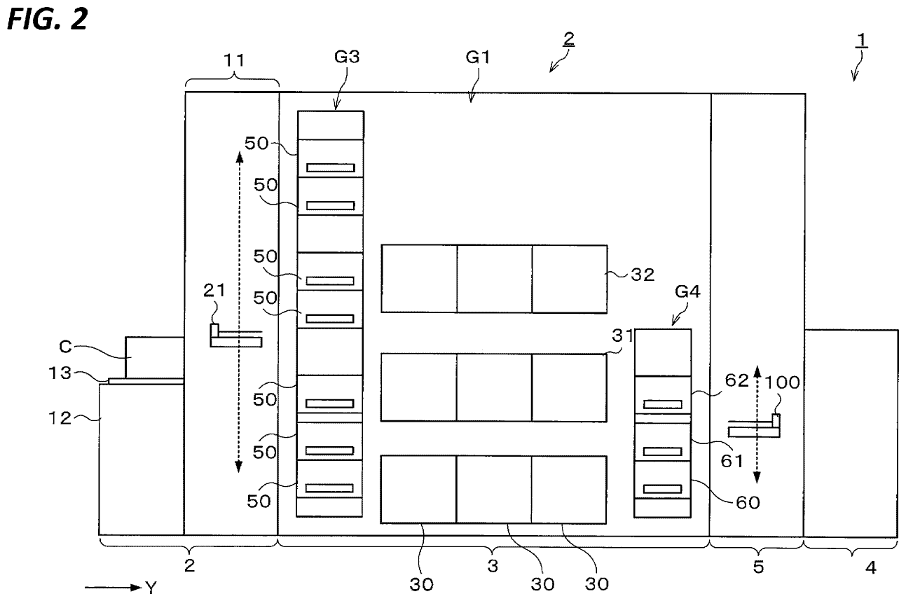

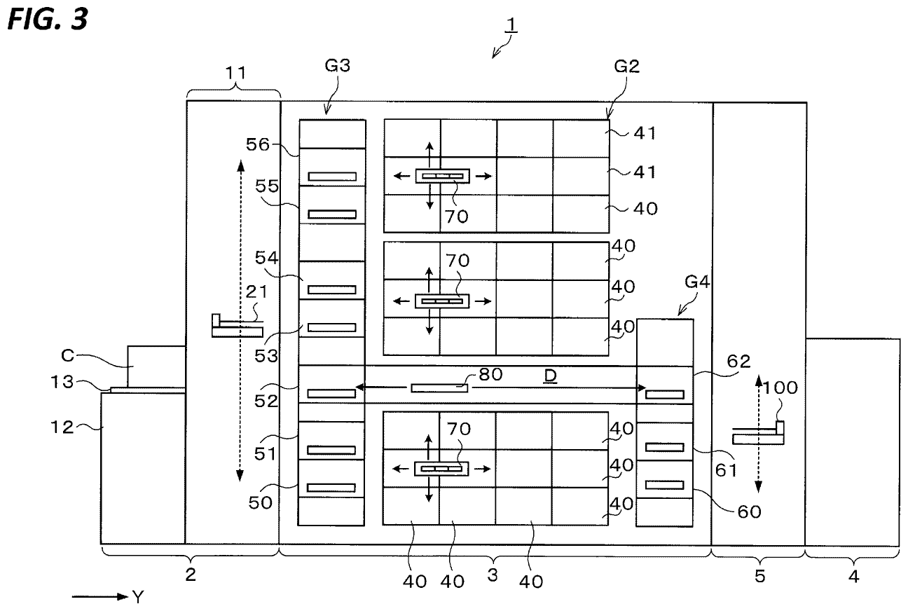

FIG. 1 is an explanatory view illustrating an outline of an internal configuration of a coating and developing system as a substrate processing system, which includes a heat treatment apparatus, according to the present embodiment. FIGS. 2 and 3 are views illustrating an outline of an internal configuration of the coating and developing system on the front and rear sides, respectively.

As illustrated in FIGS. 1 to 3, a coating and developing system 1 includes a cassette station 2 where a cassette C, which is a container capable of storing a plurality of wafers W, is loaded and unloaded, and a processing station 3 including a plurality of processing apparatuses for performing predetermined processes such as a resist coating process. Further, the coating and developing system 1 has a configuration in which the cassette station 2, the processing station 3, and an interface station 5 for delivering the wafer W between the processing station 3 and an exposure apparatus 4 adjacent thereto are integrally connected to each other.

The cassette station 2 is divided into, for example, a cassette loading and unloading section 10 and a wafer conveyance section 11. For example, the cassette loading and unloading section 10 is provided at an end portion of the coating and developing system 1 in a negative Y direction (left direction in FIG. 1). The cassette loading and unloading section 10 is provided with a cassette mounting table 12. A plurality of mounting plates 13 (for example, four) are provided on the cassette mounting table 12. The mounting plates 13 are arranged in a row horizontally in X direction (vertical direction in FIG. 1). The cassettes C may be mounted on these mounting plates 13 when loading and unloading the cassettes C to and from the outside of the coating and developing system 1.

The wafer conveyance section 11 is provided with a conveying device 20 that conveys the wafer W. The conveying device 20 is configured to be movable along a conveying path 21 extending in the X direction. The conveying device 20 is movable in the vertical direction and around the vertical axis (0 direction), and the wafer W can be conveyed between the cassette C on each mounting plate 13 and a delivery device of a third block G3 of the processing station 3 to be described herein later.

A plurality of blocks including various apparatuses, for example, four first to fourth blocks G1, G2, G3, and G4 are provided in the processing station 3. For example, the first block G1 is provided on a front side of the processing station 3 (on a side in a negative X direction in FIG. 1), and the second block G2 is provided on a rear side of the processing station 3 (on a side in a positive X direction in FIG. 1). The third block G3 is provided on the cassette station 2 side of the processing station 3 (on a side in the negative Y direction in FIG. 1), and the fourth block G4 is provided on the interface station 5 side of the processing station 3 (on a side in a positive Y direction in FIG. 1).

In the first block G1, a plurality of liquid processing apparatuses, for example, a development apparatus 30, a hard mask film forming apparatus 31, and a resist coating apparatus 32 are disposed in this order from the bottom, as illustrated in FIG. 2. The development apparatus 30 performs development on the wafer W. Specifically, the development apparatus 30 performs the development on a resist film on the wafer W that has undergone post-exposure heat (PEB) treatment. The hard mask film forming apparatus 31 performs a hard mask forming process of forming a hard mask film by coating the wafer W with a processing liquid for forming the hard mask film. The hard mask film is, for example, a zirconium oxide film. The resist coating apparatus 32 performs a resist coating process of forming a resist film by applying a resist liquid on the wafer W.

For example, three development apparatuses 30, three hard mask film forming apparatuses 31, and three resist coating apparatuses 32 are disposed side by side in the horizontal direction, respectively. In addition, the number and arrangement of the development apparatuses 30, the hard mask film forming apparatuses 31, and the resist coating apparatuses 32 may be arbitrarily selected.

In the development apparatus 30, the hard mask film forming apparatus 31, and the resist coating apparatus 32, for example, a predetermined processing liquid is coated on the wafer W by a spin coating method. In the spin coating method, for example, the processing liquid is discharged from a discharge nozzle onto the wafer W, and the wafer W is rotated to spread the processing liquid on the surface of the wafer W.

For example, in the second block G2, as illustrated in FIG. 3, heat treatment apparatuses 40 that perform heat treatment on the wafer W and high-temperature heat treatment apparatuses 41 that perform heat treatment, including heat treatment to a high temperature of 500 °C or higher, on the wafer W, are disposed side by side in the vertical and horizontal directions. The number and arrangement of the heat treatment apparatuses 40 and the high-temperature heat treatment apparatuses 41 may be arbitrarily selected. In addition, the heat treatment apparatuses 40 perform a hard mask pre-bake treatment of heat-treating the wafer W after the hard mask formation treatment and before the heat treatment by the high-temperature heat treatment apparatuses. In addition, the heat treatment apparatuses 40 perform a pre-baking process (hereinafter, referred to as “PAB treatment”) of heat-treating the wafer W after the resist coating process, a PEB process of heat-treating the wafer W after an exposure process, and a post-baking process (hereinafter, referred to as “POST treatment”) of heat-treating the wafer W after the development process, and the like. In addition, the high-temperature heat treatment apparatuses 41 perform a high-temperature heat treatment of heat-treating the wafer W after the hard mask pre-bake treatment, to a high temperature of 500 °C or higher.

For example, the third block G3 is provided with a plurality of delivery devices 50, 51, 52, 53, 54, 55, and 56 in order from the bottom. In addition, the fourth block G4 is provided with a plurality of delivery devices 60, 61, and 62 in order from the bottom.

As illustrated in FIG. 1, a wafer conveying area D is formed in an area surrounded by the first to fourth blocks G1 to G4. A conveying device 70 is disposed in the wafer conveying area D as a substrate conveying device for conveying, for example, the wafer W.

The conveying device 70 includes a conveying arm 70a movable in, for example, the Y direction, the θ direction, and the vertical direction. The conveying device 70 may move the conveying arm 70a holding the wafer W in the wafer conveying area D, and convey the wafer W to a predetermined apparatus in the first, second, third, and fourth blocks G1, G2, G3 and G4 that surround the area D. For example, as illustrated in FIG. 3, a plurality of conveying devices 70 may be disposed vertically and convey the wafer W to a predetermined apparatus at the approximately same height, for example, of each of the blocks G1 to G4.

In addition, in the wafer conveying area D, a shuttle conveying device 80 is provided to convey the wafer W linearly between the third block G3 and the fourth block G4.

The shuttle conveying device 80 may linearly move the supported wafer W in the Y direction, and convey the wafer W between the delivery device 52 of the third block G3 and the delivery device 62 of the fourth block G4 at the approximately same height.

As illustrated in FIG. 1, a conveying device 90 is provided on a side of the third block G3 in the positive X direction. The conveying device 90 includes, for example, a conveying arm 90a movable in the Y direction, the θ direction, and the vertical direction. The conveying device 90 may move the conveying arm 90a holding the wafer W vertically, and convey the wafer W to each delivery device in the third block G3.

The interface station 5 is provided with a conveying device 100 and a delivery device 101. The conveying device 100 includes, for example, a conveying arm 100a movable in the θ direction and the vertical direction. The conveying device 100 may hold the wafer W with the conveying arm 100a, and convey the wafer W between each delivery device in the fourth block G4, the delivery device 101, and the exposure apparatus 4.

The coating and developing system 1 described above is provided with at least one control unit 200, as illustrated in FIG. 1. The control unit 200 processes computer executable instructions that cause the coating and developing system 1 to execute various processes described in the present disclosure. The control unit 200 may be configured to control each element of the coating and developing system 1 to perform various processes described herein. In an embodiment, part of the control unit 200 or the entire control unit 200 may be included in the coating and developing system 1. The control unit 200 may include a processing unit, a storage unit, and a communication interface. For example, the control unit 200 is implemented by a computer. The processing unit may be configured to read from the storage unit a program that provides logic or routine that enables various control operations to be performed and execute the read program to perform various control operations. The program may be stored in the storage unit in advance or may be acquired via a medium as necessary. The acquired program is stored in the storage unit, and read out from the storage unit by the processing unit to be executed. The medium may be various computer-readable storage media H, or may be a communication line connected to the communication interface. The storage medium H may be a transitory or non-transitory medium. The processing unit may be a Central Processing Unit (CPU) or one or more circuits. The storage unit may include Random Access Memory (RAM), Read Only Memory (ROM), Hard Disk Drive (HDD), Solid State Drive (SSD), or a combination thereof. The communication interface may communicate with the coating and developing system 1 via a communication line such as a Local Area Network (LAN).

### <High-Temperature Heat Treatment Apparatus 41>

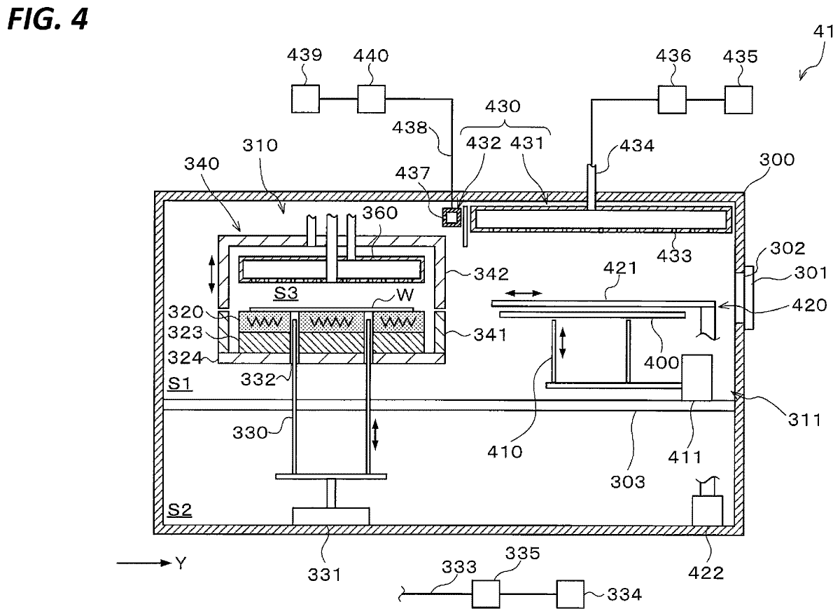

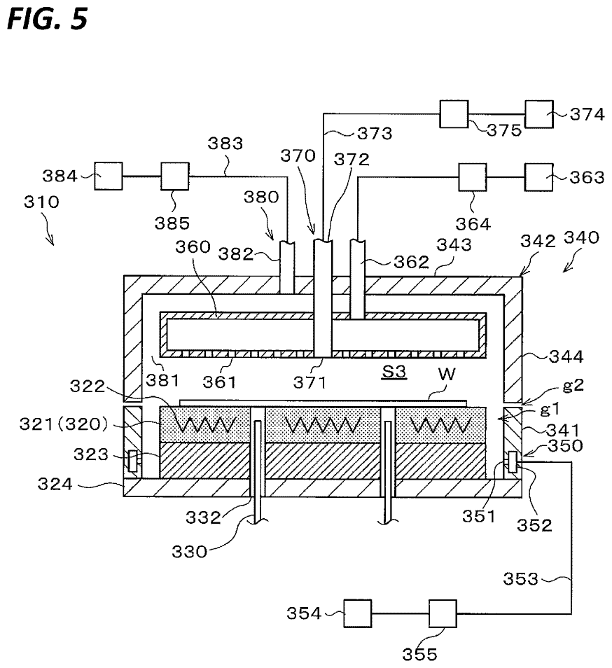

Next, the high-temperature heat treatment apparatus 41 will be described. FIG. 4 is a vertical sectional view schematically illustrating an outline of a configuration of the high-temperature heat treatment apparatus 41. FIG. 5 is a vertical sectional view schematically illustrating an outline of a configuration in a heating area 310 which will be described herein later.

As illustrated in FIG. 4, the high-temperature heat treatment apparatus 41 includes a treatment container 300 as a housing that can enclose the interior. A loading and unloading port 301 of the wafer W is formed on a sidewall of the treatment container 300 on the side of the wafer conveying area D, and an opening and closing shutter 302 is provided on the loading and unloading port 301.

The interior of the treatment container 300 is divided into an upper space S1 and a lower space S2 by a partition wall 303. The heating area 310 for heating the wafer W and a cooling area 311 for cooling the wafer W are provided in the upper space S1. The heating area 310 and the cooling area 311 are aligned in a depth direction of the apparatus (in the Y direction of the drawing), and the cooling area 311 is positioned closer to the loading and unloading port 301 than the heating area 310 is.

As illustrated in FIG. 5, the heating area 310 is provided with a heating plate 320 as a heating unit that supports and heats the wafer W to a high temperature of 500 °C or higher. The heating plate 320 includes a disk-shaped plate part 321 with a predetermined thickness. A diameter of the plate part 321 is larger than a diameter of the wafer W. For example, a heater 322 is built in the plate part 321. In addition, the plate part 321 is formed of, for example, silicon carbide having high thermal conductivity. A temperature of the heating plate 320 (specifically, the temperature of the plate part 321) is controlled by, for example, the control unit 200, and heating is performed by the heater 322 so that the wafer W placed on the heating plate 320 or the plate part 321 of the heating plate 320 reaches a predetermined temperature of 500 °C or higher.

In addition, the heating plate 320 is supported on a support bottom wall 324, for example, via a heat shielding plate 323. Both the heat shielding plate 323 and the support bottom wall 324 are formed in a disk shape. A diameter of the heat shielding plate 323 is approximately equal to a diameter of the heating plate 320. Meanwhile, a diameter of the support bottom wall 324 is larger than a diameter of the heating plate 320. The support bottom wall 324 is disposed above a partition wall 303 with a gap, as illustrated in FIG. 4. The support bottom wall 324 may be fixed to the partition wall 303 with a fixing member (not illustrated).

A plurality of lifting pins 330 (for example, three) that support and lift the wafer W from below are provided in the heating plate 320. The plurality of lifting pins 330 are lifted and lowered by a lift driving unit 331 having a driving source such as a motor. In addition, each of the lifting pins 330 is inserted into a corresponding through hole 332, and passes through the through hole 332 to protrude from an upper surface of the heating plate 320. Each of the through holes 332 is formed to penetrate through, for example, the heating plate 320, the heat shielding plate 323, the support bottom wall 324, and the partition wall 303 in the vertical direction.

The lift driving unit 331 may lift the plurality of lifting pins 330 supporting the wafer W to lift the wafer W. The lift driving unit 331 is provided, for example, in the lower space S2.

Further, in order to exhaust a treatment space S3 described herein later through the through holes 332, each through hole 332 is connected to an exhaust device 334 such as a vacuum pump, for example, via an exhaust pipe 333. The exhaust pipe 333 is provided with an exhaust equipment group 335 having valves and the like for switching ON/OFF of the exhaust through the through holes 332 (hereinafter, referred to as pin exhaust). The exhaust device 334 and the exhaust equipment group 335 are controlled by the control unit 200.

In addition, a chamber 340 is provided in the heating area 310. The chamber 340 includes a peripheral wall part 341, and an upper chamber 342 as a lid part.

As illustrated in FIG. 5, the peripheral wall part 341 is disposed with a gap g1 from the heating plate 320 (specifically the side surfaces of the heating plate 320 and the heat shielding plate 323). The peripheral wall part 341 is formed to extend upward from a peripheral edge part of the support bottom wall 324, and is also formed in an annular shape in a plan view. An inner peripheral surface of the peripheral wall part 341 faces outer peripheral surfaces of the heating plate 320 and the heat shielding plate 323. In addition, the gap g1 is formed in an annular shape in a plan view.

In addition, the peripheral wall part 341 is provided with a peripheral exhaust unit 350 that exhausts the treatment space S3 described herein later through the gap g1. The peripheral exhaust unit 350 includes a plurality of exhaust holes 351 open to the gap g1. The plurality of exhaust holes 351 are disposed in the inner peripheral surface of the peripheral wall part 341 at predetermined intervals along a peripheral direction of the peripheral wall part 341. The peripheral exhaust unit 350 further includes an exhaust passage 352 formed inside the peripheral wall part 341. The exhaust passage 352 is connected to an end of the exhaust hole 351 opposite to the gap g1. The exhaust passage 352 is formed in an annular shape in a plan view to extend along the peripheral wall part 341. In addition, an exhaust device 354 such as a vacuum pump is connected to the exhaust passage 352 via an exhaust pipe 353. The exhaust pipe 353 is provided with an exhaust equipment group 355 having a valve or the like for switching ON/OFF of the exhaust by the peripheral exhaust unit 350. The exhaust device 354 and the exhaust equipment group 355 are controlled by the control unit 200.

The upper chamber 342 covers the heating plate 320 to form the treatment space S3 above the heating plate 320. The upper chamber 342 is configured to be liftable by a lift driving unit (not illustrated). The upper chamber 342 is lowered until it comes close to the peripheral wall part 341, to form the treatment space S3.

In addition, the upper chamber 342 includes, for example, a top wall part 343 and a sidewall part 344.

The top wall part 343 is formed in a disk shape with a diameter approximately equal to that of the support bottom wall 324, and is disposed to face the upper surface of the heating plate 320.

The sidewall part 344 is formed in a cylindrical shape to extend downward from an outer edge of the top wall part 343, and is disposed so that its lower end surface faces an upper end surface of the peripheral wall part 341.

In the state where the upper chamber 342 comes close to the peripheral wall part 341, a gap g2 is formed between an upper end surface of the sidewall part 348 and a lower end surface of the peripheral wall part 341. The gap g2 is formed in an annular shape to surround the periphery of the treatment space S3.

In addition, the upper chamber 342 is configured to be heated. For example, a heater (not illustrated) is built in the top wall part 343, the heater is controlled by the control unit 200, and an upper surface of the top wall part 343 is adjusted to a predetermined temperature (e.g., 350 °C to 400 °C) that is lower than the heating plate 320.

The upper chamber 342 is formed of a metal material, specifically a stainless steel, and more specifically a SUS 304. For this reason, the surface of the upper chamber 342 on the side of the treatment space S3 is formed of a metal-containing material, and specifically, formed of a chromium oxide film formed by natural oxidation of stainless steel.

In addition, the chamber 340 includes a shower head 360 as a gas supply unit. Specifically, the upper chamber 342 includes the shower head 360.

The shower head 360 supplies low humidity gas having a lower humidity than that of atmospheric air to the treatment space S3. The low humidity gas is, for example, dry air or nitrogen gas. The humidity of the low humidity gas is adjusted so that the humidity in the treatment space S3 is, for example, 0.01% or less. The shower head 360 forms at least a part of the top wall part 343, for example.

A plurality of gas discharge holes 361 are formed on a lower surface of the shower head 360. The plurality of gas discharge holes 361 are uniformly disposed on the lower surface of the shower head 360, except for an area of an exhaust port 371 to be described herein later. A gas supply pipe 362 is connected to the shower head 360. Further, a gas supply source 363 for supplying the low humidity gas to the shower head 360 is connected to the gas supply pipe 362. In addition, the gas supply pipe 362 is provided with a supply equipment group 364 including a valve for switching ON/OFF of the low humidity gas supply to the shower head 360, a flow control valve, and the like. The control unit 200 controls the supply equipment group 364. The low humidity gas supplied from the gas supply source 363 to the shower head 360 through the gas supply pipe 362 is discharged downward from the gas discharge holes 361.

Further, the shower head 360 is provided with a central exhaust unit 370 and an outer peripheral exhaust unit 380. An exhaust unit for exhausting the treatment space S3 is formed of the central exhaust unit 370, the outer peripheral exhaust unit 380, and the peripheral exhaust unit 350 described above.

The central exhaust unit 370 exhausts the treatment space S3 from above the central part of the heating plate 320. The central exhaust unit 370 includes an exhaust port 371. The exhaust port 371 is provided in the center on the lower surface of the shower head 360 and is open downward. The central exhaust unit 370 exhausts the treatment space S3 through the exhaust port 371.

In addition, the central exhaust unit 370 includes a central exhaust passage 372 extending upward from the exhaust port 371. An exhaust device 374 such as a vacuum pump is connected to the central exhaust passage 372 via an exhaust pipe 373. The exhaust pipe 373 is provided with an exhaust equipment group 375 having a valve or the like for switching ON/OFF of the exhaust by the central exhaust unit 370. The exhaust device 374 and the exhaust equipment group 375 are controlled by the control unit 200.

The outer peripheral exhaust unit 380 exhausts the treatment space S3 from above an outer peripheral part of the heating plate 320 (specifically, from above a part slightly outside a peripheral end of the wafer W, for example). The outer peripheral exhaust unit 380 includes an exhaust port 381. The exhaust port 381 is open downward from a lower surface of the top wall part 343 to surround an outer periphery of the shower head 360. The exhaust port 381 may be a plurality of exhaust holes arranged along the outer periphery of the shower head 360. The outer peripheral exhaust unit 380 exhausts the treatment space S3 through the exhaust port 381.

In addition, the outer peripheral exhaust unit 380 includes an outer peripheral exhaust passage 382 passing through the exhaust port 381. An exhaust device 384 such as a vacuum pump is connected to the outer peripheral exhaust passage 382 via an exhaust pipe 383. The exhaust pipe 383 is provided with an exhaust equipment group 385 having a valve or the like for switching ON/OFF of the exhaust. The exhaust device 384 and the exhaust equipment group 385 are controlled by the control unit 200.

As illustrated in FIG. 4, a cooling plate 400 as a cooling unit for supporting and cooling the wafer W is provided in the cooling area 311. For example, the cooling plate 400 has a shape of a disk with a predetermined thickness. A temperature control member (not illustrated) such as coolant or a Peltier element, for example, is built in the cooling plate 400. A temperature of the cooling plate 400 is controlled by, for example, the control unit 200, and the wafer W mounted on the cooling plate 400 is cooled to a predetermined temperature.

A plurality of lifting pins 410 (for example, three) for supporting and lifting the wafer W from below are provided in the cooling plate 400. The plurality of lifting pins 410 are lifted and lowered by a lift driving unit 411 having a driving source such as a motor. In addition, each of the lifting pins 410 is inserted into a through hole (not illustrated) formed in the cooling plate 400, and may be protruded from an upper surface of the cooling plate 400 through the through hole.

The lift driving unit 411 may lift the plurality of lifting pins 410 supporting the wafer W to lift the wafer W. The lift driving unit 411 is provided in, for example, the cooling area 311 in the upper space S1.

Further, a conveying mechanism 420 for conveying the wafer W between the heating area 310 and the cooling area 311 is provided in the treatment container 300. The conveying mechanism 420 includes a holding arm 421 and a driving part 422. The holding arm 421 is provided in a space above the heating plate 320 and the cooling plate 400 in the upper space S1, and holds the wafer W horizontally. The holding arm 421 is configured to enable delivery of the wafer W with respect to the plurality of lifting pins 330 or the plurality of lifting pins 410. The driving part 422 includes a driving source such as a motor, and moves the holding arm 421 along the depth direction of the apparatus (in the Y direction in the drawing).

In addition, the treatment container 300 includes a gas supply unit 430 for supplying the low humidity gas to a space outside the chamber 340 in the treatment container 300.

The gas supply unit 430 includes a shower head 431 as a cooling area gas supply unit and a shower header 432 as a heating area gas supply unit. In addition, the type of the low humidity gas supplied from the shower head 360, the shower head 431, and the shower header 432 may be the same as or different from each other. In addition, in the following description, the type of low humidity gas supplied from the shower head 360, the shower head 431, and the shower header 432 may be the same.

The shower head 431 supplies the low humidity gas to the cooling area 311. The shower head 431 is provided in the cooling area 311, and specifically, is provided above the cooling plate 400 in the cooling area 311. A plurality of gas discharge holes 433 are formed in the lower surface of the shower head 431. The plurality of gas discharge holes 433 are uniformly disposed on the lower surface of the shower head 431. A gas supply pipe 434 is connected to the shower head 431. Further, a gas supply source 435 for supplying the low humidity gas to the shower head 431 is connected to the gas supply pipe 434. In addition, the gas supply pipe 434 is provided with a supply equipment group 436 including a valve for switching ON/OFF of the low humidity gas supply to the shower head 431, a flow control valve, and the like. The control unit 200 controls the supply equipment group 436. The low humidity gas supplied from the gas supply source 435 to the shower head 431 through the gas supply pipe 434 is discharged downward from the gas discharge hole 433.

The shower header 432 supplies the low humidity gas to the heating area 310. The shower header 432 is provided in the heating area 310. Specifically, the shower header 432 is provided between the heating plate 320 and the cooling plate 400 in the depth direction of the apparatus (in the Y direction of the drawing) in the heating area in a plan view. In addition, the shower header 432 is provided above the upper chamber 342.

Further, the shower header 432 is formed in a rod shape extending along a direction orthogonal to the depth direction of the apparatus (the Y direction of the drawing) and the vertical direction. A plurality of gas discharge holes 437 are provided in the shower header 432. The plurality of gas discharge holes 437 are formed, for example, in a surface opposite the cooling area 311 side in the shower header 432. In addition, the plurality of gas discharge holes 437 are disposed at predetermined intervals along the extending direction of the shower header 432.

Further, a gas supply pipe 438 is connected to the shower header 432. Further, a gas supply source 439 for supplying the low humidity gas to the shower header 432 is connected to the gas supply pipe 438. In addition, the gas supply pipe 438 is provided with a supply equipment group 440 including a valve for switching ON/OFF of the low humidity gas supply to the shower header 432, a flow control valve, and the like. The control unit 200 controls the supply equipment group 440. The low humidity gas supplied from the gas supply source 439 to the shower header 432 through the gas supply pipe 438 is discharged from the gas discharge hole 437 toward a space above the upper chamber 342.

### <Wafer Processing>

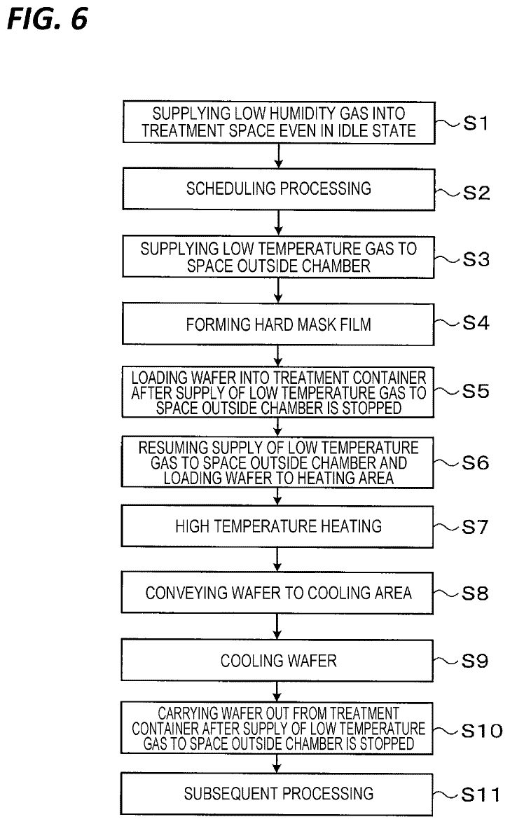

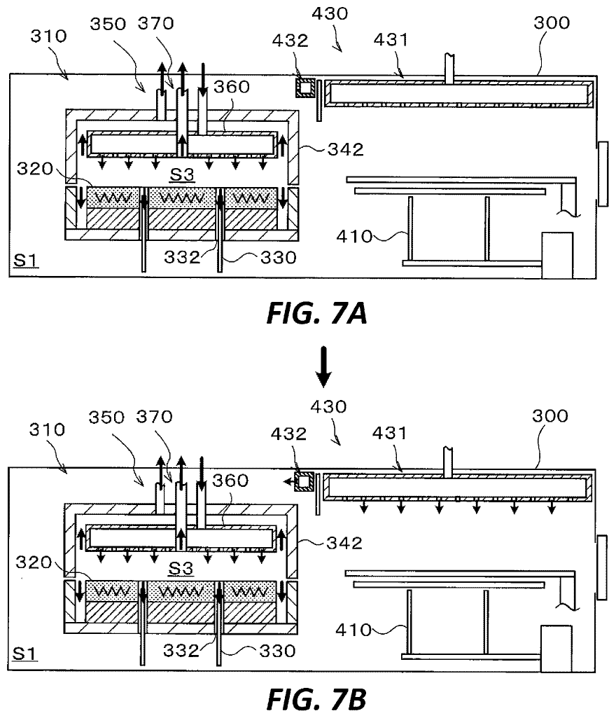

Next, an example of the processing performed by the coating and developing system 1 will be described, focusing on the processing by the high-temperature heat treatment apparatus 41. FIG. 6 is a flowchart illustrating an example of the processing performed by the coating and developing system 1. FIGS. 7A and 7B to 10 are explanatory views illustrating operations of the high-temperature heat treatment apparatus 41, respectively. In addition, the processing described below is performed under the control of the control unit 200. Further, in the following description, it is assumed that the coating and developing system 1 includes one high-temperature heat treatment apparatus 41.

As illustrated in FIG. 6, the high-temperature heat treatment apparatus 41 supplies the low humidity gas from the shower head 360 into the treatment space S3 even in an idle state (step S1). The idle state refers to a state in which the temperature of the heating plate 320 is raised (e.g., a state in which the temperature is raised to 500 °C or higher) and the processing of the wafer W by the high-temperature heat treatment apparatus 41 is not scheduled.

In the idle state, specifically, as illustrated in FIG. 7A, the upper chamber 342 is lowered to form the treatment space S3. Further, in the treatment space S3, the exhaust by the central exhaust unit 370, the exhaust by the outer peripheral exhaust unit 380, the exhaust by the peripheral exhaust unit 350, and the pin exhaust are performed, and nitrogen gas is supplied as the low humidity gas from the shower head 360 in this state. Further, in the idle state, a total exhaust flow from the treatment space S3 is set to be greater than a supply rate of nitrogen from the shower head 360 to the treatment space S3. For this reason, the treatment space S3 has a negative pressure, as compared to the space outside the chamber 340.

In this way, even in the idle state, the low humidity gas is supplied into the treatment space S3 from the shower head 360 so that the humidity in the treatment space S3 may be maintained low. In addition, by maintaining the treatment space S3 at the negative pressure as described above, leakage of gas including a constituent metal (specifically, chromium) of the upper chamber 342 to the outside of the chamber 340 may be prevented even if such gas is generated.

In addition, in the idle state, the supply of low humidity gas from the shower head 431 and the supply of low humidity gas from the shower header 432 are not performed. This is to reduce the consumption of the low humidity gas.

When a recipe for using the high-temperature heat treatment apparatus 41 is read by the control unit 200, and processing of the wafer W is scheduled for the high-temperature heat treatment apparatus 41 (step S2), the high-temperature heat treatment apparatus 41 is released from the idle state, and supply of nitrogen gas as the low humidity gas from the gas supply unit 430 to the outside of the chamber 340 in the treatment container 300 begins (step S3). For example, as illustrated in FIG. 7B, the supply of nitrogen gas from both the shower head 431 and the shower header 432 of the gas supply unit 430 begins.

In addition, the wafer W to be processed is taken out from the cassette C and conveyed to the delivery device 53 of the third block G3 of the processing station 3 by the conveying device 20.

In addition, even after the idle state is released, exhausting the treatment space S3 and supplying the nitrogen gas from the shower head 360 to the treatment space S3 are performed in the same manner as during the idle state, and the total exhaust flow from the treatment space S3 is set to be greater than the supply rate of nitrogen gas from the shower head 360.

Then, a hard mask film is formed on the wafer W (step S4).

Specifically, the wafer W is conveyed to the heat treatment apparatus 40 of the second block G2 by the conveying device 70 and subjected to temperature control processing. Then, the wafer W is conveyed to, for example, the hard mask film forming apparatus 31 of the first block G1 by the conveying device 70, and a coating film of a processing liquid for forming a chromium oxide film is formed on the wafer W. Then, the wafer W is conveyed to the heat treatment apparatus 40 of the second block G2 by the conveying device 70, subjected to the hard mask pre-bake treatment, and the coating film of the processing liquid for forming the chromium oxide film on the wafer W is solidified to form a chromium oxide film as a hard mask film. Then, the wafer W is returned to the delivery device 53 of the third block G3. Then, the wafer W is conveyed to the delivery device 54 of the same third block G3 by the conveying device 90.

Then, the supply of nitrogen gas to the outside of the chamber 340 in the treatment container 300 is stopped, and the wafer W is loaded into the treatment container 300 of the high-temperature heat treatment apparatus 41 (step S5).

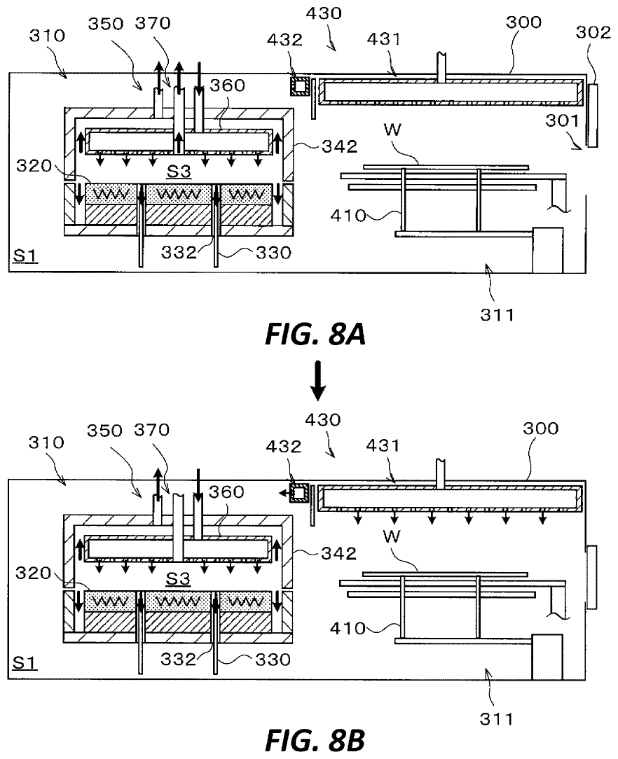

Specifically, the wafer W is conveyed by the conveying device 70 up to the loading and unloading port 301 closed by the opening and closing shutter 302 of the high-temperature heat treatment apparatus 41. In addition, the supply of nitrogen gas from the shower head 431 and the shower header 432 is stopped. Then, the loading and unloading port 301 is open by the opening and closing shutter 302 as illustrated in FIG. 8A, and the wafer W is loaded into the treatment container 300 via the loading and unloading port 301 and delivered from the conveying device 70 to the lifting pin 410 in the cooling area 311. Then, the loading and unloading port 301 is closed by the opening and closing shutter 302, and the treatment container 300 is sealed.

Then, the supply of nitrogen gas to the outside of the chamber 340 in the treatment container 300 is resumed, and after the exhaust performed by the central exhaust unit 370 is stopped, the wafer W is conveyed from the cooling area 311 to the heating area 310 (step S6).

Specifically, first, as illustrated in FIG. 8B, the supply of nitrogen gas from the shower head 431 and the shower header 432 is resumed. At the same time, the exhaust performed by the central exhaust unit 370 is stopped. The exhaust rate or the like by the outer peripheral exhaust unit 380 is set such that, even after the exhaust performed by the central exhaust unit 370 is stopped, the total exhaust flow from the treatment space S3 is greater than the supply rate of nitrogen gas from the shower head 360.

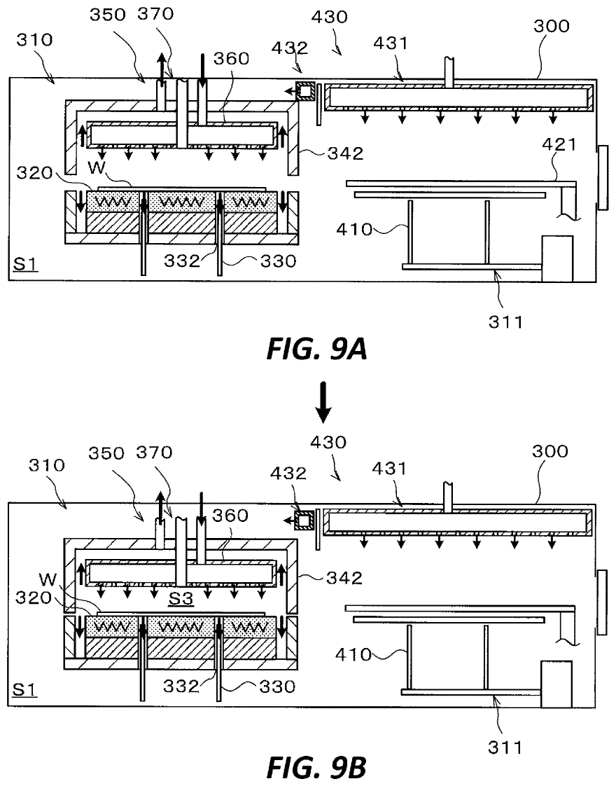

Then, the wafer W is delivered from the lifting pins 410 to the holding arm 421 of the conveying mechanism 420. Then, the upper chamber 342 is lifted, the holding arm 421 holding the wafer W is moved from the cooling area 311 to the heating area 310, and the wafer W is delivered from the holding arm 421 to the heating plate 320 via the lifting pins 330. As a result, the wafer W is mounted on the heating plate 320 as illustrated in FIG. 9A.

In this step S6, after resuming the supply of nitrogen gas, the wafer W may be allowed to wait in the cooling area 311 for a predetermined time. In addition, this waiting is unnecessary when dry air is used as the low humidity gas.

Then, the wafer W is heated to a high temperature of 500 °C or higher (step S7).

Specifically, as illustrated in FIG. 9B, when the upper chamber 342 is lowered to form the treatment space S3, the wafer W starts to be heated at a high temperature. Even during the heating at this high temperature, the total exhaust flow from the treatment space S3 is greater than the supply rate of nitrogen gas from the shower head 360.

After the start of the heating of the wafer W at the high temperature, when a predetermined time elapses, the exhaust by the central exhaust unit 370 begins. Even at this time, the exhaust rate or the like of the central exhaust unit 370 is set so that the total exhaust flow from the treatment space S3 is greater than the supply rate of nitrogen gas from the shower head 360.

After the exhaust by the central exhaust unit 370 begins, when a predetermined time elapses, the wafer W is lifted to an intermediate position by the lifting pins 330. In this state, sublimates from the hard mask film on the wafer W are recovered.

After lifting to the intermediate position, when a predetermined time elapses, the exhaust performed by the central exhaust unit 370 is stopped. Then, the upper chamber 342 is lifted. Then, the wafer W is lifted to the delivery position by the lifting pins 330. The delivery position refers to a position at which the wafer W is delivered between the lifting pins 330 and the holding arm 421 of the conveying mechanism 420.

During the heating at this high temperature, the flow rate or the like of the low humidity gas supplied to the treatment space S3 is set so that the humidity in the treatment space S3 is 0.01% or less.

Then, the wafer W is conveyed from the heating area 310 to the cooling area 311 (step S8).

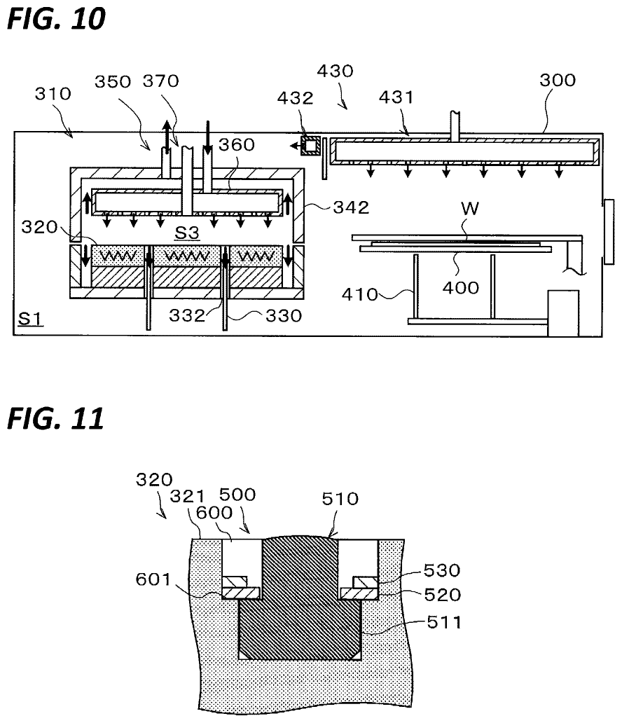

Specifically, the wafer W is delivered from the lifting pins 330 to the holding arm 421 of the conveying mechanism 420. Then, the holding arm 421 holding the wafer W is moved from the heating area 310 to the cooling area 311, and the wafer W is delivered from the holding arm 421 to the cooling plate 400 via the lifting pins 410. As a result, the wafer W is mounted on the cooling plate 400 as illustrated in FIG. 10. In addition, the upper chamber 342 is lowered to form the treatment space S3.

Then, the wafer W is cooled (step S9). Specifically, after being mounted on the cooling plate 400, the wafer W is allowed to wait for a predetermined time.

Then, the supply of nitrogen gas to the outside of the chamber 340 in the treatment container 300 is stopped, and also the wafer W is unloaded from the treatment container 300 of the high-temperature heat treatment apparatus 41 (step S10).

Specifically, the supply of nitrogen gas from the shower head 431 and the shower header 432 is stopped. Then, the loading and unloading port 301 is open by the opening and closing shutter 302, and the wafer W is delivered from the cooling plate 400 to the conveying device 70 via the lifting pins 410. Then, the wafer W is unloaded from the treatment container 300 via the loading and unloading port 301. In addition, after that, the loading and unloading port 301 is closed by the opening and closing shutter 302, and the treatment container 300 is closed again.

Then, the wafer W undergoes subsequent processing in sequence (step S11).

Specifically, the wafer W is conveyed to the resist coating apparatus 32 by the conveying device 70, and a resist film is formed on the wafer W. Then, the wafer W is conveyed to the heat treatment apparatus 40 by the conveying device 70, and the PAB treatment is performed. Then, the wafer W is conveyed to the delivery device 55 of the third block G3 by the conveying device 70.

Then, the wafer W is conveyed to the delivery device 52 by the conveying device 90, and is conveyed to the delivery device 62 of the fourth block G4 by the shuttle conveying device 80. Then, the wafer W is conveyed to the exposure apparatus 4 by the conveying device 100 of the interface station 5 and subjected to exposure processing in a predetermined pattern.

Then, the wafer W is conveyed to the delivery device 60 of the fourth block G4 by the conveying device 100. Then, the wafer W is conveyed to the heat treatment apparatus 40 by the conveying device 70 to perform PEB treatment.

Then, the wafer W is conveyed to the development apparatus 30 by the conveying device 70 and developed. After the development is completed, the wafer W is conveyed to the heat treatment apparatus 40 by the conveying device 70, and the POST treatment is performed.

Then, the wafer W is conveyed to the delivery device 50 of the third block G3 by the conveying device 70, and then conveyed to the cassette C of a predetermined mounting plate 13 by the conveying device 20 of the cassette station 2.

In this way, the processing by the series of coating and developing systems 1 is completed.

### <Material of Support Member>

Next, with reference to FIG. 11, the materials of a support member of the heating plate 320, which will be described herein later, will be described. FIG. 11 is a partial enlarged cross-sectional view of the heating plate 320.

As illustrated in FIG. 11, the heating plate 320 includes a support member 500. A plurality of support members 500 are provided in the plate parts 321 of the heating plate 320. Each support member 500 is provided in a downwardly recessed portion 600, which is individually formed in the plate part 321. A stepped portion 601 is formed on a bottom portion inside the recessed portion 600, along an inner peripheral surface of the recessed portion 600.

The support member 500 contacts a rear surface of the wafer W to support the wafer W.

The support member 500 includes a main body part 510, a washer 520 and a snap ring 530 as its components.

The main body part 510 includes a flange 511 at a lower end portion. The main body part 510 is inserted into and used within the recessed portion 600 of the heating plate 320. When the main body part 510 is inserted in the recessed portion 600, the main body part 510 is supported on the bottom surface of the recessed portion 600, and its upper end protrudes from an upper surface of the plate part 321. The upper end of the main body part 510 contacts the rear surface of the wafer W. The flange 511 has a thickness approximately equal to a height of the stepped portion 601.

The washer 520 is provided to cover an upper surface of the flange 511 in the recessed portion 600 and the upper surface of the stepped portion 601.

The snap ring 530 fixes the support member 500 to the recessed portion 600 via the washer 520.

The exposed portion of the support member 500 including the respective components described above is formed of a material other than stainless steel. Specifically, a part of the support member 500 is formed of nickel. The part of the support member 500 may be formed of a nickel alloy having higher heat resistance than stainless steel.

More specifically, for example, the main body part 510 of the support member 500 may be formed of alumina, the washer 520 may be formed of nickel, and the snap ring 530 may be formed of a nickel alloy (specifically, Inconel or Hastelloy) having higher heat resistance than stainless steel. The washer 520 may be formed of the nickel alloy described above.

### Main Effects of Present Embodiment

As described above, according to the present embodiment, the high-temperature heat treatment apparatus 41 includes the heating plate 320 configured to support and heat the wafer W to a high temperature of 500 °C or higher, the chamber 340 including the upper chamber 342 that covers the heating plate 320 to form the treatment space S3 above the heating plate 320 and has the surface formed of the metal-containing material on the side of the treatment space S3, and the exhaust unit configured to exhaust the treatment space S3. In addition, the chamber 340 includes the shower head 360 configured to supply low humidity gas having humidity lower than that of atmospheric air to the treatment space S3. Therefore, it is possible to prevent the metal-containing material on the surface of the upper chamber 342 exposed to high temperature from reacting with the moisture. Specifically, it is possible to prevent the chromium oxide (Cr₂O₃) film on the surface of the upper chamber 342 exposed to high temperature from reacting with the moisture. Accordingly, generation of gas including the constituent metal of the upper chamber 342 may be prevented. Specifically, generation of gas including chromium of the chromium oxide film on the surface of the upper chamber 342 may be prevented. As a result, adhesion of the metal to the wafer W may be prevented, and more specifically, adhesion of chromium to the surface (front surface) of the wafer W may be prevented.

Further, in the present embodiment, even in the idle state described above, the low humidity gas is supplied from the shower head 360 into the treatment space S3. For this reason, compared to when the low humidity gas is not supplied into the treatment space S3 during the idle state, as opposed to the present embodiment, adhesion of the constituent metal (specifically, chromium) of the upper chamber 342 onto the surface (front surface) of the wafer W may be prevented at the time of heat treatment at a high temperature by the high-temperature heat treatment apparatus 41 from an early time after release from the idle state.

Further, when the low humidity gas is not supplied into the treatment space S3 in the idle state unlike the present embodiment, the atmosphere including humidity in the treatment space S3 remains stagnant around the gas discharge hole 361. When the atmosphere including the residual humidity and the upper chamber 342 come into contact with each other, there is a concern that gas including the constituent metal (specifically chromium) of the upper chamber 342 may be generated. According to the present embodiment, the low humidity gas is supplied from the shower head 360 into the treatment space S3 even in the idle state, so that the stagnation described above may be prevented.

Further, in the present embodiment, the low humidity gas is supplied from the gas supply unit 430 to a space outside the chamber 340 in the treatment container 300 even when the wafer W is not present in the treatment container 300. When the treatment space S3 is at a negative pressure relative to the space outside the chamber 340, the atmosphere of the outside space flows into the treatment space S3 through the gap g2. For this reason, as described above, by supplying the low humidity gas from the gas supply unit 430 to the outside space even when no wafer W is present in the treatment container 300, compared to not supplying it, the moisture concentration in the atmosphere of the treatment space S3 may be lowered immediately after the wafer W is loaded into the treatment space S3. Accordingly, generation of gas including the constituent metal of the upper chamber 342 may be prevented.

Further, in the present embodiment, supplying the low humidity gas from the gas supply unit 430 to the space outside the chamber 340 in the treatment container 300 of the high-temperature heat treatment apparatus 41 is performed from a time point when the processing of the wafer W is scheduled for the high-temperature heat treatment apparatus 41. Specifically, in the present embodiment, when the high-temperature heat treatment apparatus 41 is in the idle state described above, the gas supply unit 430 continues to supply the low humidity gas to the space outside the chamber 340 from the time point when the processing of the wafer W is scheduled for the high-temperature heat treatment apparatus 41 and the idle state is released. That is, after release from the idle state, while the wafer W is conveyed to the high-temperature heat treatment apparatus 41, the low humidity gas is supplied from the gas supply unit 430 to the space outside the chamber 340. For this reason, after the idle state is released when the processing of the wafer W is scheduled, and the wafer W is loaded into the high-temperature heat treatment apparatus 41 and undergoes heat treatment, the moisture concentration in the atmosphere of the treatment space S3 becomes even lower. Consequently, adhesion of the constituent metal of the upper chamber 342 to the surface (front surface) of the wafer W may be further prevented at the time of heat treatment at a high temperature by the high-temperature heat treatment apparatus 41 from an early time after release from the idle state.

Furthermore, in the present embodiment, supplying the low humidity gas from the gas supply unit 430 to the space outside the chamber 340 in the treatment container 300 is stopped when the wafer W is loaded into the treatment container 300. Therefore, it is possible to prevent the leakage of low humidity gas from the treatment container 300 into the wafer conveying area D when the wafer is loaded into the treatment container 300. This is especially useful when the low humidity gas is nitrogen gas.

Further, in the present embodiment, the exposed part of the support member 500 is formed of a material other than stainless steel. Specifically, the part of the support member 500 is formed of a nickel alloy having higher heat resistance than nickel or stainless steel. As a result, adhesion of the constituent metal (specifically chromium) of the upper chamber 342 to the rear surface of the wafer W may be prevented.

According to the experiments conducted by the inventors, when the washer 520 and the snap ring 530 are formed of SUS304, the amount of chromium detected on the rear surface of the wafer W was approximately 2.4×10¹⁰ atoms/cm². In contrast, when the washer 520 is formed of nickel and the snap ring 530 is formed of Inconel, it was approximately 0.2×10¹⁰ atoms/cm².

### <Modification>

Unlike the example described above in which the low humidity gas supplied from the gas supply unit 430 is supplied from both the shower head 431 and the shower header 432, the gas is supplied from only one of them.

The present embodiment described herein should be considered to be an example and not limited in all respects. The embodiments described above may be omitted, replaced, or changed in various forms without deviating from the scope and the gist of the attached claims. For example, the configuration requirements of the embodiments described above may be optionally combined. From the arbitrary combination, the action and effect of each configuration requirement for the combination can be naturally obtained, and other actions and effects obvious to the person skilled in the art can be obtained from the description of this specification.

Further, the effects described in the description are only explanatory or exemplary and not limited. That is, the technology pertaining to the present disclosure may have other effects that are clear to the person skilled in the art from the description provided herein together with or in lieu of the effects described above.

In addition, the following configuration examples also fall within the technical scope of the present disclosure.
(1) A heat treatment apparatus, including:
a heating unit that supports and heats a substrate to a high temperature of 500 °C or higher;
a chamber including a lid part that covers the heating unit to define a treatment space above the heating unit and has a surface formed of a metal-containing material on a side of the treatment space; and
an exhaust unit that exhausts the treatment space,
in which the chamber includes a gas supply unit that supplies a low humidity gas having lower humidity than atmospheric air, to the treatment space.
(2) The heat treatment apparatus described in (1) above, in which the metal-containing material is stainless steel.
(3) The heat treatment apparatus described in (1) or (2) above, further including a control unit,
in which by a control of the control unit, the heat treatment apparatus executes (A) a process of supplying the low humidity gas from the gas supply unit into the treatment space, while the heating unit is at a raised temperature and no processing of the substrate is scheduled for the heat treatment apparatus.
(4) The heat treatment apparatus described in (3) above, further including:
a housing that accommodates the heating unit and the chamber; and
a separate gas supply unit that supplies the low humidity gas to a space outside the chamber within the housing,
in which by the control of the control unit, the heat treatment apparatus executes (B) a process of supplying the low humidity gas from the separate gas supply unit to the space outside the chamber within the housing, and
the process (B) is performed even when no substrate is present in the housing.
(5) The heat treatment apparatus described in (4) above, in which the process (B) is performed from a time point when the processing of the substrate is scheduled for the heat treatment apparatus until the scheduled processing of the substrate is completed.
(6) The heat treatment apparatus described in (5) above, in which the process (B) is stopped when a substrate is loaded into the housing.
(7) The heat treatment apparatus described in any one of (4) to (6) above, further including a cooling unit that is provided in a cooling area adjacent to a heating area in which the heating unit is provided, within the housing, and supports and cools the substrate,
in which the separate gas supply unit includes a heating area gas supply unit that supplies the low humidity gas to the heating area and a cooling area gas supply unit that supplies the low humidity gas to the cooling area, and
the process (B) supplies the low humidity gas from at least one of the heating area gas supply unit and the cooling area gas supply unit.
(8) The heat treatment apparatus described in any one of (1) to (7) above, in which
the heating unit includes a support member that supports the substrate in contact with a rear surface of the substrate, and
an exposed part of the support member is formed of a material other than stainless steel.
(9) The heat treatment apparatus described in (8) above, in which a part of the support member is formed of nickel alloy having higher heat resistance than nickel or stainless steel.
(10) A heat treatment method of a substrate using a heat treatment apparatus, in which the heat treatment apparatus includes:
a heating unit that supports and heats the substrate to a high temperature;
a chamber including a lid part that covers the heating unit to define a treatment space above the heating unit, and has a surface formed of a metal-containing material on a side of the treatment space; and
an exhaust unit that exhausts the treatment space,
the heat treatment method including:
(a) a process of heating the substrate to a high temperature of 500 °C or higher by the heating unit,
(b) a process of supplying a low humidity gas having lower humidity than atmospheric air to the treatment space.
(11) The heat treatment method described in (10) above, in which the metal-containing material is stainless steel.
(12) The heat treatment method described in (10) or (11) above, in which the process (b) is performed even when the heating unit is at a raised temperature and no processing of the substrate is scheduled for the heat treatment apparatus.
(13) The heat treatment method described in (12) above, in which
the heat treatment apparatus further includes a housing that accommodates the heating unit and the chamber,
the heat treatment method further includes (c) a process of supplying the low humidity gas to a space outside the chamber within the housing, and
the process (c) is performed even when the substrate is not present in the housing.
(14) The heat treatment method described in (13), in which the process (c) is performed from a time point when the processing of the substrate is scheduled for the heat treatment apparatus until the scheduled processing of the substrate is completed.
(15) The heat treatment method described in (14) above, in which the process (c) is stopped when the substrate is loaded into the housing.
(16) The heat treatment method described in any one of (13) to (15) above, in which the heat treatment apparatus further includes:
a cooling unit that is provided in a cooling area adjacent to a heating area in which the heating unit is provided, within the housing, and supports and cools the substrate;
a heating area gas supply unit that supplies the low humidity gas to the heating area;
a cooling area gas supply unit that supplies the low humidity gas to the cooling area,
in which the process (c) supplies the low humidity gas from at least one of the heating area gas supply unit and the cooling area gas supply unit.

Description of Symbols

| | |
|---|---|
| 41 | high-temperature heat treatment apparatus |
| 320 | heating plate |
| 340 | chamber |
| 342 | upper chamber |
| 350 | peripheral exhaust unit |
| 370 | central exhaust unit |
| 380 | outer peripheral exhaust unit |
| 381 | exhaust port |
| S3 | treatment space |
| W | wafer |

1. A heat treatment apparatus comprising:
a heater configured to support and heat a substrate to a high temperature of 500 °C or higher;
a chamber including a lid that covers the heater to define a treatment space above the heater and has a surface formed of a metal-containing material on a side of the treatment space; and
an exhaust port configured to exhaust the treatment space,
wherein the chamber includes a gas supply that supplies a low humidity gas having lower humidity than atmospheric air, to the treatment space.

2. The heat treatment apparatus according to claim 1, wherein the metal-containing material is stainless steel.

3. The heat treatment apparatus according to claim 1, further comprising:
a controller,
wherein by a control of the controller, the heat treatment apparatus executes (A) supplying the low humidity gas from the gas supply into the treatment space, while the heater is at a raised temperature, and no processing of the substrate is scheduled for the heat treatment apparatus.

4. The heat treatment apparatus according to claim 3, further comprising:
a housing configured to accommodate the heater and the chamber; and
a separate gas supply configured to supply the low humidity gas to a space outside the chamber within the housing,
wherein by the control of the controller, the heat treatment apparatus executes (B) supplying the low humidity gas from the separate gas supply to the space outside the chamber within the housing, and
(B) is performed even when no substrate is present in the housing.

5. The heat treatment apparatus according to claim 4, wherein (B) is performed from a time point when the processing of the substrate is scheduled for the heat treatment apparatus until the scheduled processing of the substrate is completed.

6. The heat treatment apparatus according to claim 5, wherein (B) is stopped when a substrate is loaded into the housing.

7. The heat treatment apparatus according to claim 4, further comprising:
a cooler provided in a cooling area adjacent to a heating area in which the heater is provided, within the housing, and configured to support and cool the substrate,
wherein the separate gas supply includes a heating area gas supply that supplies the low humidity gas to the heating area and a cooling area gas supply that supplies the low humidity gas to the cooling area, and
(B) supplies the low humidity gas from at least one of the heating area gas supply and the cooling area gas supply.

8. The heat treatment apparatus according to claim 1, wherein the heater includes a support that supports the substrate in contact with a rear surface of the substrate, and
an exposed part of the support is formed of a material other than stainless steel.

9. The heat treatment apparatus according to claim 8, wherein a part of the support is formed of nickel alloy having higher heat resistance than nickel or stainless steel.

10. A heat treatment method comprising:
(a) providing a heat treatment apparatus including
a heater configured to support and heat a substrate to a high temperature,
a chamber including a lid that covers the heater to define a treatment space above the heater and has a surface formed of a metal-containing material on a side of the treatment space, and
an exhaust port configured to exhaust the treatment space;
(b) heating the substrate to a high temperature of 500 °C or higher by the heater;
(c) supplying a low humidity gas having lower humidity than atmospheric air, to the treatment space.

11. The heat treatment method according to claim 10, wherein the metal-containing material is stainless steel.

12. The heat treatment method according to claim 10, wherein (c) is performed even when the heater is at a raised temperature and no processing of the substrate is scheduled for the heat treatment apparatus.

13. The heat treatment method according to claim 12, wherein the heat treatment apparatus further includes a housing that accommodates the heater and the chamber,
the heat treatment method further comprises (d) supplying the low humidity gas to a space outside the chamber within the housing, and
(d) is performed even when the substrate is not present in the housing.

14. The heat treatment method according to claim 13, wherein (d) is performed from a time point when the processing of the substrate is scheduled for the heat treatment apparatus until the scheduled processing of the substrate is completed.

15. The heat treatment method according to claim 14, wherein (d) is stopped when the substrate is loaded into the housing.

16. The heat treatment method according to claim 13, wherein the heat treatment apparatus further includes:
a cooler that is provided in a cooling area adjacent to a heating area in which the heater is provided, within the housing, and supports and cools the substrate;
a heating area gas supply that supplies the low humidity gas to the heating area; and
a cooling area gas supply that supplies the low humidity gas to the cooling area, and
(d) supplies the low humidity gas from at least one of the heating area gas supply and the cooling area gas supply.
